(19) United States
(12) Patent Application Publication
(10) Pub. No.: US 2023/0171928 A1
(43) Pub. Date: Jun. 1, 2023

(54) THERMAL MODULES WITH SOLDER-FREE THERMAL BONDS

(71) Applicant: HEWLETT-PACKARD DEVELOPMENT COMPANY, L.P., SPRING, TX (US)

(72) Inventors: CHI HAO CHANG, TAIPEI CITY (TW); HENDRY HUANG, TAIPEI CITY (TW); KUAN-TING WU, TAIPEI CITY (TW)

(21) Appl. No.: 17/995,876

(22) PCT Filed: Apr. 10, 2020
(86) PCT No.: PCT/US2020/027704

§ 371 Date: Oct. 10, 2022

(51) Int. Cl. H05K 7/20

(52) U.S. Cl. CPC H05K 7/2039; H05K 7/20336

(57) ABSTRACT

The present disclosure describes thermal modules having solder-free thermal bonds, methods of forming the thermal modules, and electronic devices that include the thermal modules. In one example, a thermal module having a solder-free thermal bond can include an assembly of a heat pipe and a heat sink mechanically connected to the heat pipe at a bonding junction area. The bonding junction area can include a gap between the heat pipe and the heat sink at a portion of the bonding junction area. A ther-mal coating composition can coat the assembly and fill the gap. The thermal coating composition can include a cured resin and thermally conductive particles.

### BACKGROUND

Electronic devices and circuitry can generate excess heat. Appropriate heat management can increase reliability of electronic devices and can prevent premature failure. Accordingly, a variety of heat transfer methodologies have been developed to manage the excess heat generated by these electronic devices and circuitry. Non-limiting examples can include heat sinks, cold plates, convective air cooling, forced air cooling, heat pipes, Peltier cooling plates, etc.

As one specific example, a heat pipe can operate on the principle of repeated or continuous evaporation and condensation of a working fluid. More specifically, heat input vaporizes a liquid component of the working fluid inside an evaporator section of the heat pipe. The vapor flows towards the colder condenser section of the heat pipe, where the vapor condenses and gives up its latent heat. The condensed liquid returns to the evaporator and the two-phase flow circulation continues while a temperature gradient is maintained between the evaporator and the condenser.

### BRIEF DESCRIPTION OF THE DRAWINGS

FIG. 1A is a cross-sectional view of an example assembly in accordance with examples of the present disclosure;

FIG. 1B is a magnified cross-sectional view of the example assembly of FIG. 1A in accordance with examples of the present disclosure;

FIG. 1C is another magnified cross-sectional view of the example assembly of FIG. 1A in accordance with examples of the present disclosure;

FIG. 1D is a further magnified cross-sectional view of the example assembly of FIG. 1A in accordance with examples of the present disclosure;

FIG. 2 is a cross-sectional view of an example thermal module in accordance with examples of the present disclosure;

FIG. 3 is a flow diagram of an example method of forming a thermal module in accordance with examples of the present disclosure; and

FIG. 4 is a schematic representation of an example electronic device in accordance with examples of the present disclosure.

### DETAILED DESCRIPTION

The present disclosure describes thermal modules with solder-free thermal bonds. In one example, a thermal module having a solder-free thermal bond includes an assembly that includes a heat pipe and a heat sink mechanically connected to the heat pipe at a bonding junction area. The bonding junction area includes a gap between the heat pipe and the heat sink at a portion of the bonding junction area. A thermal coating composition coats the assembly and fills the gap. The thermal coating composition includes a cured resin and thermally conductive particles. In some examples, the thermal coating composition can fill the bonding junction area such that the bonding junction area is devoid of air bubbles. In further examples, the cured resin can be a UV-cured resin or a thermally cured resin. In certain examples, the cured resin can include polyurethane, polyacrylic, urethane acrylate, acrylic acrylate, epoxy acrylate, polyester, polyester-polyether copolymer, polyamide-polyether copolymer, or a combination thereof. In some examples, the thermally conductive particles can include copper, aluminum, graphite, graphene, aluminum nitride, beryllium oxide, silicon carbide, or a combination thereof. In certain examples, from about 50 wt% to about 100 wt% of the thermally conductive particles can have a particle size less than 1 micrometer. In further examples, the thermal coating composition can include the thermally conductive particles in an amount from about 5 wt% to about 60 wt%.

The present disclosure also describes methods of forming thermal modules with a solder-free thermal bond. In one example, a method of forming a thermal module with a solder-free thermal bond includes positioning a heat pipe in mechanical connection with a heat sink at a bonding junction area to form an assembly, wherein the bonding junction area includes a gap between the heat pipe and the heat sink at a portion of the bonding junction area. A thermal coating composition is applied to the assembly to fill the gap. The thermal coating composition includes a curable resin and thermally conductive particles. In some examples, the thermal coating composition can be applied by dipping the assembly in the thermal coating composition. In certain examples, the assembly can be dipped in the thermal coating composition under vacuum, or under ultrasonic vibration, or under vacuum and ultrasonic vibration. In further examples, the thermal coating composition can be cured. Curing can include heating the thermal coating composition, exposing the thermal coating composition to UV light, or both. In various examples, the curable resin can include polyurethane, polyacrylic, urethane acrylate, acrylic acrylate, epoxy acrylate, polyester, polyester-polyether copolymer, polyamide-polyether copolymer, or a combination thereof, and the thermally conductive particles can include copper, aluminum, graphite, graphene, aluminum nitride, beryllium oxide, silicon carbide, or a combination thereof, and from about 50 wt% to about 100 wt% of the thermally conductive particles can have a particle size less than 1 micrometer.

The present disclosure also describes electronic devices that include thermal modules. In one example, an electronic device includes an electronic component capable of generating heat and a thermal module having a solder-free thermal bond. The thermal module includes an assembly made up of a heat pipe and a heat sink mechanically connected to the heat pipe at a bonding junction area. The heat pipe is also thermally connected to the electronic component to conduct heat from the electronic component. The bonding junction area includes a gap between the heat pipe and the heat sink at a portion of the bonding junction area. A thermal coating composition coats the assembly and fills the gap. The thermal coating composition includes a cured resin and thermally conductive particles. In some examples, the thermal coating composition can fill the bonding junction area such that the bonding junction area is devoid of air bubbles. In further examples, the cured resin can include polyurethane, polyacrylic, urethane acrylate, acrylic acrylate, epoxy acrylate, polyester, polyester-polyether copolymer, polyamide-polyether copolymer, or a combination thereof, and the thermally conductive particles can include copper, aluminum, graphite, graphene, aluminum nitride, beryllium oxide, silicon carbide, or a combination thereof, and from about 50 wt% to about 100 wt% of the thermally conductive particles can have a particle size less than 1 micrometer.

It is noted that when discussing the thermal modules, electronic devices including the thermal modules, and methods described herein, these discussions can be considered applicable to one another whether or not they are explicitly discussed in the context of that example. Thus, for example, when discussing a thermal coating composition related to a thermal module, such disclosure is also relevant to and directly supported in the context of methods and devices, vice versa, etc.

It is also understood that terms used herein will take on their ordinary meaning in the relevant technical field unless specified otherwise. In some instances, there are terms defined more specifically throughout the specification or included at the end of the present specification, and thus, these terms have a meaning as described herein.

### Thermal Modules Having Solder-Free Thermal Bonds

In many electronic devices, heat pipes can be included for heat management. A heat pipe can be thermally connected to an electronic component that produces heat while the electronic device is running. The heat pipe can contain a working fluid that can evaporate in a section of the heat pipe near the hot electronic component. This evaporation can draw heat out of the electronic component. The vapor can then flow to a colder section of the heat pipe, where the vapor can condense. In some cases, the colder section of the heat pipe can be connected to a heat sink. A variety of heat sink designs can be used. In some examples, the heat sink can include fins or pins or another such structure with a high surface area. The high surface area can allow the heatsink to be cooled by radiation and convection of air around the heat sink. Heat sinks are often made of a material with high thermal conductivity, such as aluminum.

Heat sinks are sometimes connected to heat pipes by soldering. In some cases, soldering can create a bond with good thermal conductivity between the heat pipe and the heat sink. However, solder can often include toxic ingredients and soldering may not be environmentally friendly. In order to avoid the use of solder, the heat pipe and the heat sink can be connected through mechanical bonding. A mechanical bond can be formed by placing the heat pipe and the heat sink in close physical contact. Unfortunately, in many cases gaps can remain between the heat pipe and the heat sink. The gaps can be due to surface defects in the surfaces of the heat pipe or the heat sink, and/or due to mismatches in the shape of the heat pipe and heat sink. In some examples, gaps can be several micrometers or more in width. These gaps can reduce the thermal conductivity of the bond between the heat pipe and the heat sink.

The technology described herein can form a solder-free bond between a heat pipe and a heat sink with increased thermal conductivity. The heat pipe and heat sink can be mechanically connected to form an assembly. The heat pipe and heat sink can be connected at a bonding junction area. The bonding junction area can include a gap between the heat pipe and the heat sink. A thermal coating composition can coat the assembly and fill the gap between the heat sink and the heat pipe. The thermal coating composition can include a cured resin and thermally conductive particles. Because of the thermally conductive particles, the thermal coating can have a high thermal conductivity overall. Therefore, filling the gaps with the thermal coating can increase heat conductance between the heat pipe and the heat sink.

In certain examples, a heat pipe and a heat sink can be mechanically connected to form an assembly, and then the assembly can be dipped into the thermal coating composition. This can be done under vacuum so that the thermal coating composition can fill all the gaps without any air bubbles being retained in the gaps. In other examples, ultrasonic vibrations can be used to eliminate air bubbles. Because the assembly is dipped in the thermal coating composition, the exterior surfaces of the assembly can also be coated with the composition. Thus, a highly thermally conductive thermal module can be made.

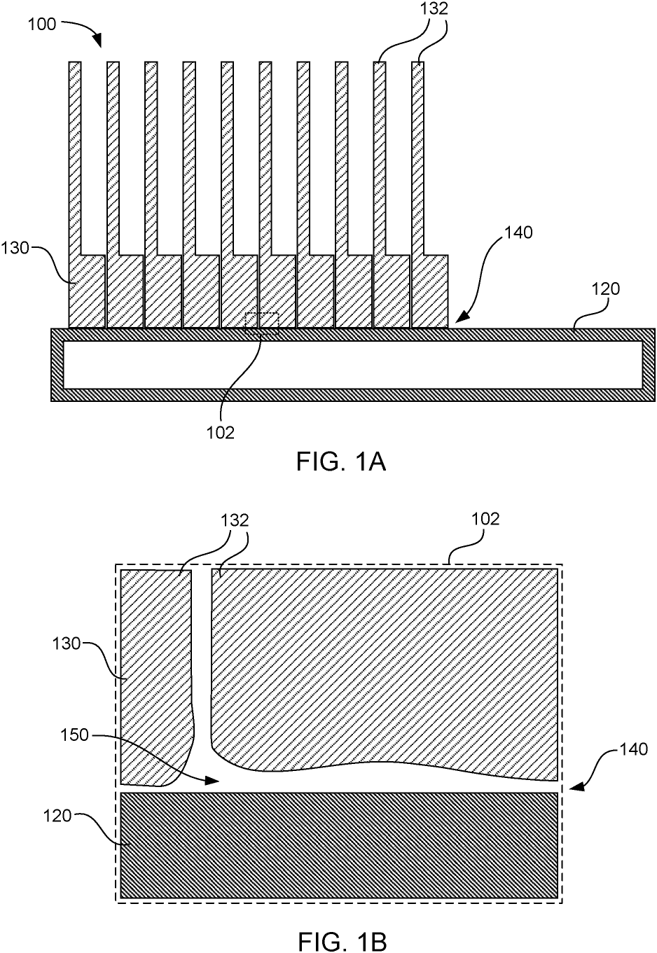

FIG. 1A shows a cross-section view of one example of an assembly 100 including a heat pipe 120 mechanically connected to a heat sink 130 at a bonding junction area 140. In this example, the heat sink includes a plurality of fins 132. The fins have a thicker portion at the base that is mechanically connected to the heat pipe and a thinner portion for allowing air to flow between the fins. Although it is not apparent from this view, small gaps can be present between the heat sink and the heat pipe in the bonding junction area. A portion of FIG. 1A within the dotted box 102 is shown in a magnified view in FIG. 1B.

FIG. 1B shows a magnified view of the bonding junction area 140 between the heat pipe 120 and the heat sink 130. The bases of two of the fins 132 are shown. In this figure, a gap 150 can be seen between the fins and the surface of the heat pipe. The gap can be due to surface irregularities of the heat sink and heat pipe, or to mismatches between the shape of the heat sink and the heat pipe, or to misalignments of fins in the heat sink, or all of the above. Although the gap is small, the gap can reduce thermal conductance between the heat pipe and the heat sink.

FIG. 1C shows the same view of the bonding junction area 140 after the heat pipe 120 and the heat sink 130 have been coated by a thermal coating composition 160. The thermal coating composition fills the gap 150. The thermal coating composition can include a cured resin and thermally conductive particles. The thermal coating composition can have a high thermal conductivity compared to air. Therefore, filling the gap with the thermal coating composition can increase heat conductance between the heat pipe and the heat sink. A portion of the gap inside the dotted box 104 is shown in a magnified view in FIG. 1D.

FIG. 1D shows a magnified view of the gap 150 between the heat pipe 120 and the heat sink 130. This view shows that the thermal coating composition includes a cured resin 162 and thermally conductive particles 164. The thermally conductive particles can be distributed throughout the cured resin and held in place by the cured resin. The thermally conductive particles can be included in an amount sufficient to increase the thermal conductivity of the thermal coating composition.

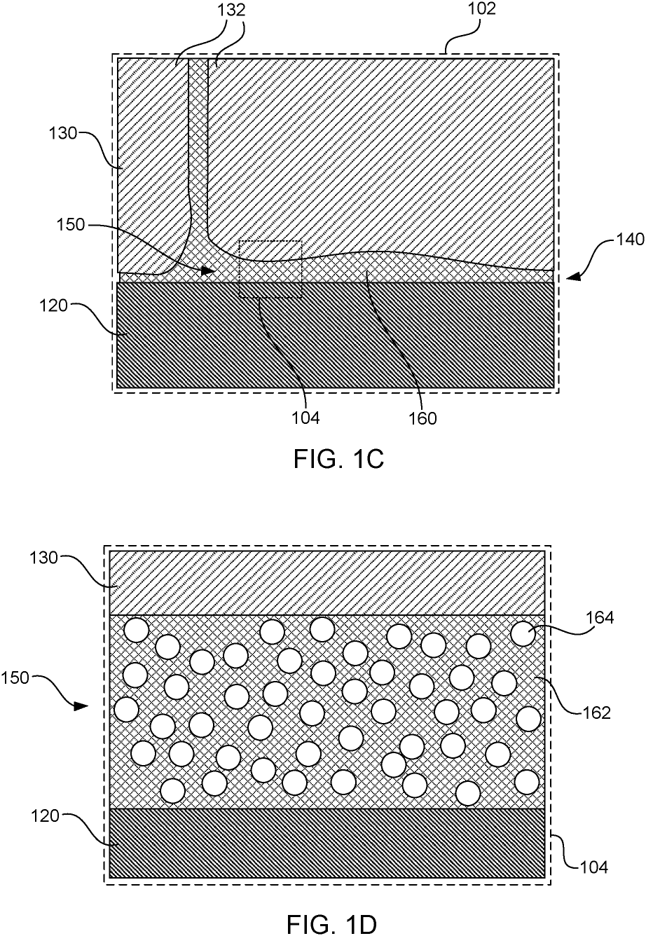

Another example thermal module 200 is shown in FIG. 2. This figure shows a cross-sectional view of the thermal module, which includes an assembly 100 made up of a heat pipe 120 mechanically connected to a heat sink 130 at a bonding junction area 140. In this example, the heat sink includes a plurality of fins 132 that are mechanically connected to the heat pipe. Small gaps 150 are present in some locations between the fins and the heat pipe. A thermal coating composition 160 coats the assembly and fills the gaps between the fins and the heat pipe. The thermal coating composition can include a cured resin and thermally conductive particles.

A thermal module such as the example shown in FIG. 2 can be made by dipping an assembly of a heat pipe and a heat sink into the thermal coating composition. In the example shown in FIG. 2, the thermal coating is present on the surfaces of the heat sink and a portion of the surface of the heat pipe. Another portion of the heat pipe does not have the thermal coating. This type of coating can be made by dipping the bottom portion of the heat pipe, where the heat sink is attached, into the thermal coating composition. Although the heat pipe is not entirely coated by the thermal coating composition, this example can still be described as having the thermal coating composition “coating the assembly” of the heat pipe and the heat sink. In various examples, an assembly “coated” by the thermal coating composition can include an assembly in which the heat pipe and the heat sink are both completely coated by the thermal coating composition, or an assembly in which the heat sink is completely coated and the heat pipe is partially coated, or an assembly in which the heat sink is partially coated and the heat pipe is completely coated, or an assembly in which the heat sink and the heat pipe are both partially coated. Depending on the shapes of the heat pipe and the assembly, it may be convenient to hold either the heat pipe or the heat sink, or both, at certain locations while dipping the assembly into the thermal coating composition. Thus, in various examples, certain portions of the heat sink and/or the heat pipe may not be submerged in the thermal coating composition when dipping. However, in some examples, the bonding junction area can be completely coated with the thermal coating composition, so that the thermal coating composition can fill in any gaps in the bonding junction area.

As used herein, “bonding junction area” can refer to portions of the surfaces of the heat pipe and the heat sink that are designed to be in contact for transferring heat from the heat pipe to the heat sink. This can include locations where the surface of the heat pipe is actually in physical contact with the surface of the heat sink, and areas where gaps between the heat pipe and the heat sink prevent physical contact. Depending on the surface irregularities, shape mismatches, misalignments, and other factors that can cause gaps, the bonding junction area can include more areas in physical contact or more areas with gaps. In some examples, the portion of the bonding junction area that has direct physical contact between the surface of the heat pipe and the surface of the heat sink can be from about 1% to about 95%, or from about 1% to about 90%, or from about 5% to about 75%, or from about 5% to about 50% or from about 10% to about 40%, or from about 10% to about 25%.

Heat pipes can include a thermally conductive metal forming a hollow shape with an interior cavity. In some examples, the overall shape of the heat pipe can be a tube, but other shapes are also possible. The interior cavity can contain a working fluid. The working fluid can include a liquid phase and a vapor phase. The liquid can evaporate in a section of the heat pipe where the temperature is high. This evaporation can draw heat from the walls of the heat pipe in the hot section, thereby cooling a hot electronic component that is connected to the heat pipe. The working fluid vapor can then condense in another, cooler area of the heat pipe. In some examples, this area can be connected to a heat sink to dissipate heat.

In some examples, the thermally conductive metal in the walls of the heat pipe can include a material having a thermal conductivity of from about 180 watts per meter-kelvin (W/mK) to about 500 W/mK. In some further examples, the thermally conductive metal can include copper, silver, gold, aluminum, or an alloy thereof. In some examples, the working fluid can have a latent heat of evaporation of from about 800 kilojoules per kilogram (kJ/kg) to about 2500 kJ/kg. In some additional examples, the working fluid can include water, ammonia, methanol, ethanol, glycerol, or a combination thereof. In certain examples, the interior cavity of the heat pipe can be evacuated before the working fluid is introduced and sealed inside the cavity. Thus, the cavity can be occupied by the working fluid liquid and vapor without any air or other materials, in some examples.

In further detail, in some examples, the heat pipe walls can include a thermally conductive material having a thermal conductivity of from about 180 watts per meter-kelvin (W/mK) to about 500 W/mK. In some additional examples, the thermally conductive material can be or include a material having a thermal conductivity of from about 180 W/mK to about 300 W/mK, from about 250 W/mK to about 350 W/mK, from about 300 W/mK to about 400 W/mK, from about 350 W/mK to about 450 W/mK, or from about 400 W/mK to about 500 W/mK. It is emphasized that these thermal conductivity values refer to the thermal conductivity rating for the material itself, not the heat pipe. For example, pure copper has a thermal conductivity of about 401 W/mK. In contrast, the thermal conductivity of a copper heat pipe can vary depending on the length thereof, which will be discussed in greater detail below.

In some specific examples, the thermally conductive material can be or include copper, silver, gold, aluminum, the like, or an alloy thereof. In some examples, the thermally conductive material can be or include copper or an alloy thereof. In some additional examples, the thermally conductive material can be or include silver or an alloy thereof. In yet additional examples, the thermally conductive material can be or include gold or an alloy thereof. In still additional examples, the thermally conductive material can be or include aluminum or an alloy thereof.

Regarding the working fluid, a variety of working fluids can be employed in the heat pipe. Working fluids can be chosen based on the temperature at which the heat pipe is intended to operate. For example, the working fluid can be selected from fluids that are compatible with the thermally conductive material of the heat pipe and that will provide both a vapor phase and a liquid phase over the intended operating temperature range. Additionally, the working fluid can typically have a high latent heat of evaporation. In some examples, the working fluid can have a latent heat of evaporation of from about 800 kilojoules per kilogram (kJ/kg) to about 2500 kJ/kg. In some further examples, the working fluid can have a latent heat of evaporation of from about 800 kJ/kg to about 1500 kJ/kg, from about 1200 kJ/kg to about 1800 kJ/kg, from about 1500 kJ/kg to about 2000 kJ/kg, from about 1800 kJ/kg to about 2200 kJ/kg, or from about 2000 kJ/kg to about 2500 kJ/kg.

In some specific examples, the working fluid can be or include water, ammonia, methanol, ethanol, glycerol, the like, or a combination thereof. In some examples, the working fluid can be or include water. In some additional examples, the working fluid can be or include ammonia. In yet additional examples, the working fluid can be or include methanol. In still additional examples, the working fluid can be or include ethanol. In some further examples, the working fluid can be or include glycerol. It is noted that not all working fluids are compatible with all thermally conductive materials. For example, a water working fluid may not be compatible with a vapor chamber formed of aluminum. However, a water working fluid can be compatible with a vapor chamber formed of copper and an ammonia working fluid can be compatible with a vapor chamber formed of aluminum, for example.

Heat pipes can have a variety of dimensions depending on the size of the electronic devices in which the heat pipes are used. In some examples, heat pipes can have an outer diameter or outer width from about 2 mm to about 20 mm, or from about 2 mm to about 10 mm, or from about 20 mm to about 6 mm, or from about 4 mm to about 8 mm, or from about 6 mm to about 10 mm. The inner diameter, or width of the interior cavity, can be from about 1.5 mm to about 18 mm, or from about 1.5 mm to about 10 mm, or from about 1.5 mm to about 8 mm, or from about 1.5 mm to about 5 mm, or from about 3 mm to about 6 mm, or from about 4 mm to about 7 mm, or from about 5 mm to about 8 mm, in some examples. The wall thickness of the heat pipe, or the difference between the outer diameter and inner diameter, can be from about 0.2 mm to about 2 mm in some examples. In further examples, the wall thickness can be from about 0.2 mm to about 1.5 mm, or from about 0.2 mm to about 1.5 mm, or from about 0.3 mm to about 1 mm, or from about 0.3 mm to about 0.5 mm, or from about 0.4 mm to about 0.6 mm, or from about 0.5 mm to about 0.7 mm, or from about 0.6 mm to about 0.8 mm.

The heat pipe can have a length sufficient to run from an electronic component that produces heat to a heat sink that dissipates heat. In some examples, the length of the heat pipe can be from about 50 mm to about 500 mm. In further examples, the length of the heat pipe can be from about 50 mm to about 150 mm, from about 100 mm to about 200 mm, from about 150 mm to about 250 mm, from about 200 mm to about 300 mm, from about 250 mm to about 350 mm, from about 300 mm to about 400 mm, from about 350 mm to about 450 mm, or from about 400 mm to about 500 mm. The overall thermal conductivity of the heat pipe can depend on the length of the heat pipe. In some examples, depending on the length of the heat pipe and the thermally conductive material employed, the heat pipe can have a thermal conductivity of from about 10,000 W/mK to about 100,000 W/mK, for example.

Heat sinks used in the thermal modules described herein can also be made from a thermally conductive material. In some examples, the heat sinks can be made from copper, silver, gold, aluminum, steel, or alloys thereof. In certain examples, the heat sink can be made from a different material than the heat pipe. In a particular example, the heat sink can include aluminum or an aluminum alloy and the heat pipe can include copper.

The heat sink can have a variety of features for dissipating heat. In some examples, the heat sink can have a high surface area for its size. To achieve a high surface area, heat sinks can include features such as fins, pins, coils, and so on. In some examples, these features can be separated by air gaps to allow heat to be dissipated into the air between the features. The size of the features and the gaps can be designed to allow for high heat dissipation and good air flow in some examples. In certain examples, the heat sink can include fins or pins having a thickness from about 0.1 mm to about 5 mm, or from about 0.1 mm to about 1 mm, or from about 0.1 mm to about 0.5 mm, or from about 0.2 mm to about 0.6 mm, or from about 0.3 mm to about 0.7 mm, or from about 0.4 mm to about 0.8 mm, or from about 0.5 mm to about 1 mm. The height and width of the fins or pins can be selected depending on the size constraints of the particular electronic device. In some examples, fins can have a height and width that are independently from about 1 mm to about 100 mm, from about 1 mm to about 50 mm, from about 10 mm to about 50 mm, from about 10 mm to about 30 mm, from about 20 mm to about 40 mm, or other dimensions depending on the particular electronic device. Pins can have a height of similar dimensions. Fins or pins can be spaced apart with a spacing distance from about 0.5 mm to about 10 mm, or from about 0.5 mm to about 5 mm, or from about 1 mm to about 5 mm, or from about 2 mm to about 6 mm, or from about 3 mm to about 7 mm, or from about 4 mm to about 8 mm, or from about 5 mm to about 10 mm, depending on the desired density and overall surface area of the heat sink.

In some examples, the heat sink can be mechanically connected to the heat pipe in a location distant from the electronic component that produces heat, from which the heat pipe is designed to remove heat. The heat sink can be connected to the heat pipe in a portion of the heat pipe where the working fluid condenses. When the working fluid condenses, the latent heat of condensation can be conducted through the wall of the heat pipe to the heat sink. This heat can then be dissipated by the heat sink. In some cases, a metal coupling may also be connected to the heat pipe near the electronic component that produces heat. For example, a metal coupling can be in contact with the heat pipe and with the electronic component. The coupling can help secure the heat pipe to the electronic component and/or the coupling can help conduct heat out of the electronic component and into the heat pipe. Such a coupling can also be described as a “heat sink” as used herein, and this type of heat sink can also be attached to the heat pipe using the methods described herein. For example, a metal coupling can be attached by mechanically connecting the coupling to the heat pipe to form an assembly, and coating the assembly with a thermal coating composition so that the thermal coating composition fills gaps between the heat pipe and the coupling. Accordingly, such metal couplings are included in the “heat sinks” described herein.

Heat sinks can dissipate heat in several ways. Some heat sinks can be passive heat sinks, which can be designed to dissipate heat to still air surrounding the heat sink. In some cases, convection of the air can be induced by temperature differences caused by heat from the heat sink. In other examples, heat sinks can include a fan to force air to move past the heat sink. Additionally, some heat sinks can dissipate heat into another fluid besides air, such as water cooled heat sinks, heat sinks cooled by another heat transfer fluid besides water, cryogenically cooled heat sinks, and so on.

The heat sink can be mechanically connected to the heat pipe to form an assembly. In some examples, the heat sink can be mechanically bonded to the heat pipe by a variety of mechanical bonding methods. In one example, the heat sink can be placed adjacent to the heat pipe so that a surface of the heat sink touches a surface of the heat pipe. Although the heat sink may be placed in apparent physical contact with the heat pipe, there can be gaps between the heat sink and the heat pipe due to surface irregularities, shape mismatches, and so on as explained above. In further examples, the heat sink can be mechanically connected to the heat pipe by clamping, pressing, pressure fitting, and other methods. In some cases, the shape of the heat pipe or heat sink can be altered in the bonding junction area. For example, a heat pipe that is tube-shaped can be altered to have a more square or rectangular cross-section in the bonding junction area so that the heat sink can be mechanically connected to a flat surface of the heat pipe. In other examples, the heat sink can have a different shape at the bonding junction area than in the fins or pins. In some examples, a heat sink can include a base portion with multiple fins or pins protruding from the base portion. However, the base portion can have a larger flat surface that can be mechanically connected to the heat pipe.

Even when every effort is made to place the heat sink and heat pipe in physical contact at the bonding junction area, gaps can still remain in various locations within the bonding junction area. In some examples, gaps can have a gap width from about 1 micrometer to about 10 mm, or from about 1 micrometer to about 1 mm, or from about 2 micrometers to about 500 micrometers, or from about 5 micrometers to about 100 micrometers, or from about 10 micrometers to about 50 micrometers.

As mentioned above, a thermal coating composition can be used to fill the gaps between the heat sink and the heat pipe. The thermal coating composition can include a curable resin and thermally conductive particles. After the thermal coating composition has been applied to fill the gap between the heat sink and the heat pipe, the resin can be cured to form a cured resin. The cured resin can hold the thermally conductive particles in place within the gap.

A variety of curable resins can be used in the thermal coating composition. In some examples, the curable resin can be a UV-curable (i.e., ultraviolet radiation curable) resin, a thermally curable resin, or a combination thereof. In certain examples, the UV-curable resin can include a polyacrylic, a polyurethane, a urethane acrylate, an acrylic acrylate, an epoxy acrylate, or a combination thereof. In certain examples, the UV-curable resin can include a photoinitiator that can initiate polymerization when exposed to UV radiation. In a particular example, the UV-curable resin can be a polyacrylic with or without a photoinitiator. In another example, the UV-curable resin can be a polyurethane with or without a photoinitiator. In yet another example, the UV-curable resin can be a urethane acrylate with or without a photoinitiator. In still another example, the UV-curable resin can be an acrylic acrylate with or without a photoinitiator. In another example, the UV-curable resin can be an epoxy acrylate with or without a photoinitiator.

In some examples, UV-curable resins can be cured by exposing the resin to UV radiation of a sufficient intensity for a sufficient time to cure the resin. In certain examples, the intensity can be from about 500 mJ/cm² to about 1500 mJ/cm², or from about 600 mJ/cm² to about 1400 mJ/cm², or from about 700 mJ/cm² to about 1300 mJ/cm². The irradiation time can be from about 5 seconds to about 1 minute, or from about 10 seconds to about 30 seconds, or from about 15 seconds to about 30 seconds. In certain examples, curing the UV-curable resin can also include baking before or after UV irradiation. Baking can be at a temperature from about 50° C. to about 100° C., or from about 50° C. to about 70° C., or from about 50° C. to about 60° C., for a baking time from about 1 minute to about 20 minutes, or from about 5 minutes to about 15 minutes, or from about 5 minutes to about 10 minutes.

In other examples, the curable resin can be thermally curable. In certain examples, thermally curable resins can include a polyurethane, a polyacrylic, a polyester, a polyester-polyether copolymer, a polyamide-polyether copolymer, or a combination thereof. In a particular example, the thermally curable resin can be a polyurethane. In another example, the thermally curable resin can be a polyacrylic. In another example, the thermally curable resin can be a polyester. In another example, the thermally curable resin can be a polyester-polyether copolymer. In another example, the thermally curable resin can be a polyamide-polyether copolymer. The thermally curable resin can be cured by heating, in some examples. In certain examples, the thermally curable resin can be cured by heating at a temperature from about 50° C. to about 100° C., or from about 60° C. to about 80° C., or from about 50° C. to about 60° C. The heating time can be from 10 minutes to about 1 hour, or from about 15 minutes to about 40 minutes, or from about 20 minutes to about 30 minutes.

In various examples, the curable resin can be a liquid that can be cured to form a solid resin. In some examples, the curable resin can be made up of liquid monomers and/or polymers that can be cured to form a solid polymer. In other examples, the curable resin can include dispersed solid polymer particles that can be cured to form a cohesive solid polymer. In some examples, the polymer particles can have an average particle size from about 1 micrometer to about 50 micrometers, or from about 5 micrometers to about 30 micrometers, or from about 10 micrometers to about 25 micrometers.

The thermally conductive particles in the thermal coating composition can be any small particles of a solid material that has a relatively high thermal conductivity. In some examples, the thermally conductive particles can be made of a material having a thermal conductivity from about 100 W/mK to about 500 W/mK, or from about 150 W/mK to about 400 W/mK, or from about 180 W/mK to about 350 W/mK. In certain examples, the thermally conductive particles can include copper, aluminum, graphite, graphene, aluminum nitride, beryllium oxide, silicon carbide, or a combination thereof. In further examples, the thermally conductive particles can have an average particle size from about 100 nm to about 10 micrometers. In further examples, the average particle size can be from about 500 nm to about 5 micrometers, or from about 500 nm to about 1 micrometer. In some examples, from about 50 wt% to 100 wt% of the thermally conductive particles can have a particle size less than about 1 micrometer.

The concentration of the thermally conductive particles in the thermal coating composition can be sufficient to give the coating composition, as a whole, a good thermal conductivity. In some examples, the concentration of thermally conductive particles in the thermal coating composition can be from about 5 wt% to about 60 wt%, or from about 10 wt% to about 50 wt%, or from about 20 wt% to about 50 wt%.

### Methods of Forming Thermal Modules

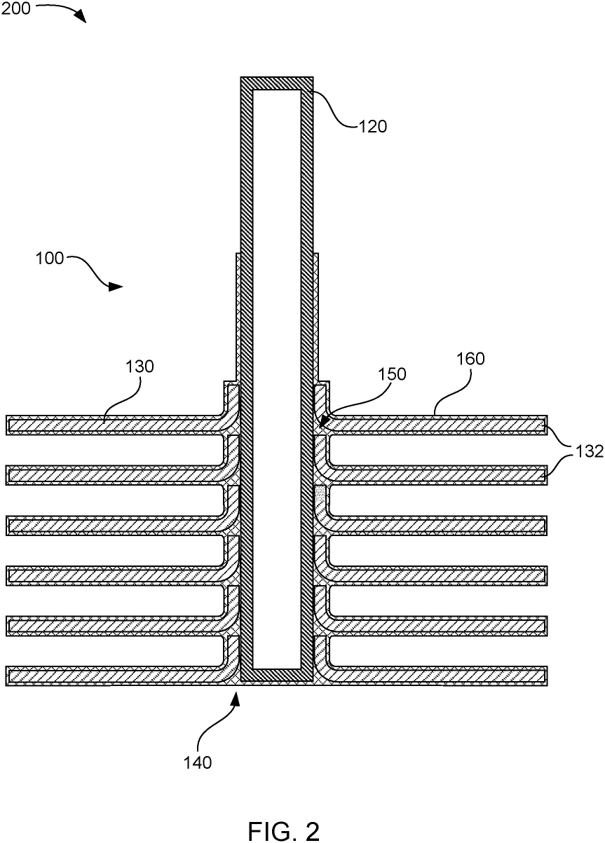

The present disclosure also describes methods of forming the thermal modules described herein. FIG. 3 is a flowchart illustrating an example method 300 of forming a thermal module with a solder-free thermal bond. The method includes: positioning a heat pipe in mechanical connection with a heat sink at a bonding junction area to form an assembly, wherein the bonding junction area includes a gap between the heat pipe and the heat sink at a portion of the bonding junction area 310; and applying a thermal coating composition to the assembly to fill the gap, wherein the thermal coating composition includes a curable resin and thermally conductive particles 320.

As mentioned above, in some examples the assembly can be dipped in the thermal coating composition. Thus, some or all of the exterior surfaces of the heat sink and/or heat pipe can be coated with the thermal coating composition. Additionally, gaps between the heat pipe and the heat sink at the bonding junction area can be filled by the thermal coating composition. In some examples, the gaps can be completely filled so that no air bubbles remain in the bonding junction area. In certain examples, the assembly can be dipped into the thermal coating composition under vacuum and/or with ultrasonic vibrations to help eliminate air bubbles from the gaps.

The methods described herein can also include curing the curable resin in the thermal coating composition using the curing conditions described above. In some examples, the assembly can be heated to cure the resin. In other examples, the assembly can be exposed to UV radiation. In further examples, the assembly can be heated and exposed to UV radiation.

In a particular example, the thermal coating composition can include a UV-curable resin. In this example, the heat sink can be an aluminum heat sink that includes a plurality of aluminum fins, and the heat pipe can include copper walls. In this example, the method can include mechanically connecting the heat sink to the heat pipe to form an assembly, then dipping the assembly into the thermal coating composition under vacuum to fill gaps between the heat sink and the heat pipe. The assembly can be removed from the thermal coating composition bath and then cured by baking for about 5 minutes to about 10 minutes at about 50° C. to about 60° C., and then exposing the UV radiation at an intensity from about 700 mJ/cm² to about 1300 mJ/cm² for about 10 seconds to about 30 seconds.

In another particular example, the thermal coating composition can include a thermally curable resin. Again, in this example, the heat sink can be an aluminum heat sink that includes a plurality of aluminum fins, and the heat pipe can include copper walls. In this example, the heat sink and heat pipe can be mechanically connected and dipped into the thermal coating composition as in the previous example. The assembly can be withdrawn from the thermal coating composition bath and the resin can be cured. In this example, the thermally curable resin can be cured by heating at about 60° C. to about 80° C. for about 15 minutes to about 40 minutes.

### Electronic Devices

The thermal modules disclosed herein can be used in a variety of electronic devices. Non-limiting examples can include a display, an amplifier, a memory device, a server, a modem, a router, a personal computer, a laptop computer, a tablet, a phone, a speaker, a television, a media player, a projector, a smart device, or a combination thereof.

In further detail, the electronic device can include a heat-generating component. For example, with demands for increased speeds and smaller sizes of electronic devices, microprocessors are becoming smaller with more compressed cores. This can cause higher rates of heat generation per unit area of the microprocessor. As another example, temperatures can increase with smaller transistor designs because smaller channel dimensions can increase the power density and electron-phonon non-equilibrium within devices, for example. Further still, increasing temperatures can result from increasing numbers of metal layers in interconnects between transistors, resulting in increased current densities and aspect ratios. Thus, a variety of components, including increasingly smaller components, in electronic devices can generate high amounts of heat that can benefit from thermal management.

In some examples, the electronic device can include a component capable of generating heat that is connected to the heat pipe of the thermal module described herein. The heat pipe can conduct heat away from the heat-generating component. The thermal module can include a heat sink connected to the heat pipe, with gaps between the heat pipe and the heat sink filled by the thermal coating composition as described herein. Thus, heat produced by the heat-generating component can be conducted away by the heat pipe and dissipated by the heat sink. Additionally, as explained above, in some examples a coupling can be connected to the heat pipe and the heat-generating component. Such a coupling can also be connected to the heat pipe using the thermal coating composition to fill gaps between the coupling and the heat pipe.

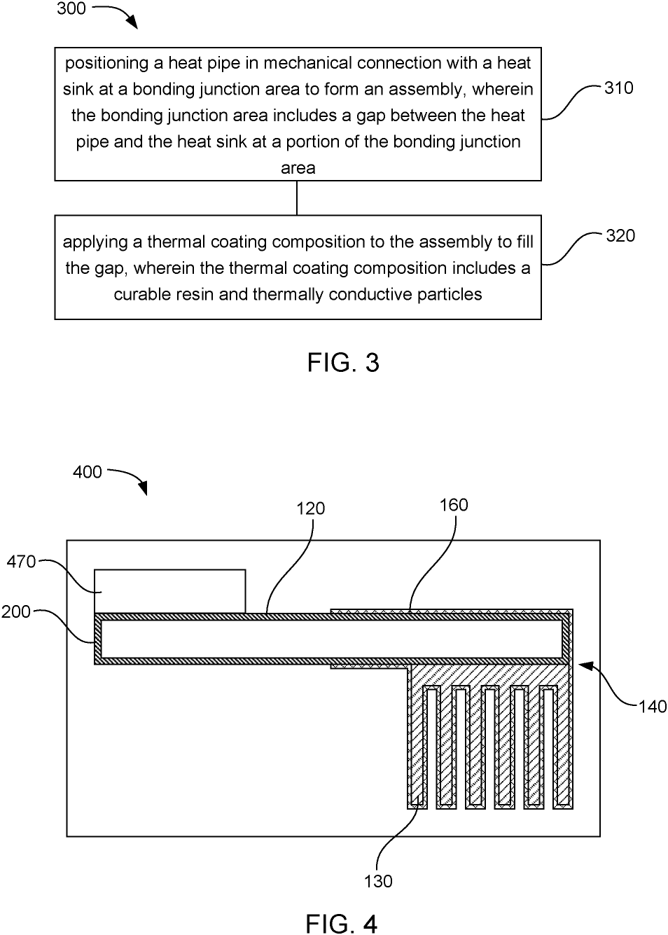

One schematic representation of an electronic device 400 is illustrated in FIG. 4. The electronic device can include a heat-generating component 470 and a thermal module 200. The thermal module can include an assembly of a heat pipe 120 and a heat sink 130 mechanically connected to the heat pipe at a bonding junction area 140. The heat pipe is also thermally connected to the heat-generating component to conduct heat away from the component. A thermal coating composition 160 fills a gap (not visible in this figure) between the heat sink and the heat pipe. This thermal coating composition can include a cured resin and thermally conductive particles as described above.

### Definitions

It is noted that, as used in this specification and the appended claims, the singular forms “a,” “an,” and “the” include plural referents unless the content clearly dictates otherwise.

As used herein, the term “about” is used to provide flexibility to a numerical range endpoint by providing that a given value may be “a little above” or “a little below” the endpoint. The degree of flexibility of this term can be dictated by the particular variable and would be within the knowledge of those in the field technology to determine based on experience and the associated description herein.

As used herein, a plurality of items, structural elements, compositional elements, and/or materials may be presented in a common list for convenience. However, these lists should be construed as though individual members of the list are individually identified as a separate and unique member. Thus, no individual member of such list should be construed as a de facto equivalent of any other member of the same list solely based on their presentation in a common group without indications to the contrary.

Concentrations, dimensions, amounts, and other numerical data may be presented herein in a range format. It is to be understood that such range format is used merely for convenience and brevity and should be interpreted flexibly to include the numerical values explicitly recited as the limits of the range, and also all the individual numerical values or sub-ranges encompassed within that range as if individual numerical values and sub-ranges are explicitly recited. For example, an atomic ratio range of about 1 at% to about 20 at% should be interpreted to include the explicitly recited limits of about 1 at% and about 20 at%, and also to include individual atomic percentages such as 2 at%, 11 at%, 14 at%, and sub-ranges such as 10 at% to 20 at%, 5 at% to 15 at%, etc.

The terms, descriptions, and figures used herein are set forth by way of illustration and are not meant as limitations. Many variations are possible within the disclosure, which is intended to be defined by the following claims -- and equivalents -- in which all terms are meant in the broadest reasonable sense unless otherwise indicated.

### EXAMPLES

The following illustrates examples of the present disclosure. However, it is to be understood that the following are merely illustrative of the application of the principles of the present disclosure. Numerous modifications and alternative devices, methods, and systems may be devised without departing from the spirit and scope of the present disclosure. The appended claims are intended to cover such modifications and arrangements.

### Example 1 - Solder-Free Thermal Bond With Thermal Curing Resin

An example thermal module is constructed by the following process. First, a copper heat pipe is mechanically connected to an aluminum heat sink by pressure fitting the heat pipe into a space in the aluminum heat sink designed to fit the heat pipe. After mechanically connecting the heat pipe to the heat sink, small gaps are present in some locations between the heat pipe and the heat sink. The assembly, including the heat pipe and the heat sink, is dipped into a bath of a thermal coating composition under vacuum. The thermal coating composition coats the assembly and fills in the gaps.

The thermal coating composition in this example includes a thermal curing polyurethane resin mixed with copper particles. The copper particles are present in an amount of about 40 wt%, and the polyurethane is present in an amount of 60 wt%. The copper particles have an average particle size of less than 1 micrometer.

After withdrawing the assembly from the thermal coating bath, the assembly is heated at a temperature of 80° C. for 15 minutes to cure the thermal curing polyurethane. After curing, the thermal module is complete.

### Example 2 - Solder-Free Thermal Bond With UV Curing Resin

Another example thermal module is constructed by the following process. As in Example 1, a copper heat pipe is mechanically connected to an aluminum heat sink by pressure fitting the heat pipe into a space in the aluminum heat sink designed to fit the heat pipe. After mechanically connecting the heat pipe to the heat sink, small gaps are present in some locations between the heat pipe and the heat sink. The assembly, including the heat pipe and the heat sink, is dipped into a bath of a thermal coating composition under vacuum. The thermal coating composition coats the assembly and fills in the gaps.

The thermal coating composition in this example includes a UV curing polyacrylic resin mixed with copper particles. The copper particles are present in an amount of about 40 wt%, and the polyacrylic is present in an amount of 60 wt%. The copper particles have an average particle size of less than 1 micrometer.

After withdrawing the assembly from the thermal coating bath, the assembly is baked at 50° C. for 10 minutes and then exposed to UV radiation at an intensity of 700 mJ/cm² for 30 seconds to cure the UV curing polyacrylic resin. After curing, the thermal module is complete.

What is claimed is:

1. A thermal module having a solder-free thermal bond comprising:
an assembly comprising a heat pipe and a heat sink mechanically connected to the heat pipe at a bonding junction area, wherein the bonding junction area includes a gap between the heat pipe and the heat sink at a portion of the bonding junction area;
a thermal coating composition coating the assembly and filling the gap, wherein the thermal coating composition comprises a cured resin and thermally conductive particles.

2. The thermal module of claim 1, wherein the thermal coating composition fills the bonding junction area such that the bonding junction area is devoid of air bubbles.

3. The thermal module of claim 1, wherein the cured resin is a UV-cured resin or a thermally cured resin.

4. The thermal module of claim 1, wherein the cured resin comprises polyurethane, polyacrylic, urethane acrylate, acrylic acrylate, epoxy acrylate, polyester, polyester-polyether copolymer, polyamide-polyether copolymer, or a combination thereof.

5. The thermal module of claim 1, wherein the thermally conductive particles comprise copper, aluminum, graphite, graphene, aluminum nitride, beryllium oxide, silicon carbide, or a combination thereof.

6. The thermal module of claim 1, wherein from about 50 wt% to about 100 wt% of the thermally conductive particles have a particle size less than 1 micrometer.

7. The thermal module of claim 1, wherein the thermal coating composition includes the thermally conductive particles in an amount from about 5 wt% to about 60 wt%.

8. A method of forming a thermal module with a solder-free thermal bond comprising:
positioning a heat pipe in mechanical connection with a heat sink at a bonding junction area to form an assembly, wherein the bonding junction area includes a gap between the heat pipe and the heat sink at a portion of the bonding junction area;
applying a thermal coating composition to the assembly to fill the gap, wherein the thermal coating composition comprises a curable resin and thermally conductive particles.

9. The method of claim 8, wherein applying the thermal coating composition comprises dipping the assembly in the thermal coating composition.

10. The method of claim 9, wherein the assembly is dipped in the thermal coating composition under vacuum, or under ultrasonic vibration, or under vacuum and ultrasonic vibration.

11. The method of claim 8, further comprising curing the thermal coating composition, wherein the curing comprises heating the thermal coating composition, exposing the thermal coating composition to UV light, or both.

12. The method of claim 8, wherein the curable resin comprises polyurethane, polyacrylic, urethane acrylate, acrylic acrylate, epoxy acrylate, polyester, polyester-polyether copolymer, polyamide-polyether copolymer, or a combination thereof, and wherein the thermally conductive particles comprise copper, aluminum, graphite, graphene, aluminum nitride, beryllium oxide, silicon carbide, or a combination thereof, and wherein from about 50 wt% to about 100 wt% of the thermally conductive particles have a particle size less than 1 micrometer.

13. An electronic device comprising:
an electronic component capable of generating heat; and
a thermal module having a solder-free thermal bond comprising:
an assembly comprising a heat pipe and a heat sink mechanically connected to the heat pipe at a bonding junction area, wherein the heat pipe is also thermally connected to the electronic component to conduct heat from the electronic component, and wherein the bonding junction area includes a gap between the heat pipe and the heat sink at a portion of the bonding junction area, and
a thermal coating composition coating the assembly and filling the gap, wherein the thermal coating composition comprises a cured resin and thermally conductive particles.

14. The electronic device of claim 13, wherein the thermal coating composition fills the bonding junction area such that the bonding junction area is devoid of air bubbles.

15. The electronic device of claim 13, wherein the cured resin comprises polyurethane, polyacrylic, urethane acrylate, acrylic acrylate, epoxy acrylate, polyester, polyester-polyether copolymer, polyamide-polyether copolymer, or a combination thereof, and wherein the thermally conductive particles comprise copper, aluminum, graphite, graphene, aluminum nitride, beryllium oxide, silicon carbide, or a combination thereof, and wherein from about 50 wt% to about 100 wt% of the thermally conductive particles have a particle size less than 1 micrometer.
